(19) United States
(12) Patent Application Publication
(10) Pub. No.: US 2017/0338282 A1
(43) Pub. Date: Nov. 23, 2017

(54) MEMORY MODULE WITH UNPATTERNED STORAGE MATERIAL

(71) Applicant: Intel Corporation, Santa Clara, CA (US)

(72) Inventors: Umberto M. MEOTTO, Rivoli (IT); Fabio PELLIZZER, Cornate d'Adda Province -MB (IT)

(21) Appl. No.: 15/161,068

(22) Filed: May 20, 2016

(51) Int. Cl. H01L 27/24; H01L 45/00

(52) U.S. Cl. CPC H01L 27/2472; H01L 45/16; H01L 27/2481; H01L 45/1233; H01L 45/141

(57) ABSTRACT

An array of memory cells includes a layer of nonpatterned storage material, in accordance with embodiment. In one embodiment, a circuit includes an array of memory cells. The array of memory cells includes first conductive electrodes. The array includes a layer of storage material including a nonpatterned region disposed over the first conductive electrodes. The array includes second conductive electrodes disposed over the nonpatterned region of the storage material. A given memory cell of the array is located where one of the second conductive electrodes overlaps one of the first conductive electrodes across the nonpatterned region of storage material.

### FIELD

Embodiments of the invention are generally related to memory devices, and more particularly to arrays of singularly addressable memory cells including unpatterned storage material.

### COPYRIGHT NOTICE/PERMISSION

Portions of the disclosure of this patent document may contain material that is subject to copyright protection. The copyright owner has no objection to the reproduction by anyone of the patent document or the patent disclosure as it appears in the Patent and Trademark Office patent file or records, but otherwise reserves all copyright rights whatsoever. The copyright notice applies to all data as described below, and in the accompanying drawings hereto, as well as to any software described below: Copyright © 2016, Intel Corporation, All Rights Reserved.

### BACKGROUND

Memory resources have innumerable applications in electronic devices and other computing environments. Continued drive to smaller and more energy efficient devices has resulted in scaling issues with traditional memory devices. Thus, there is a current demand for memory devices that can potentially scale smaller than traditional memory devices.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing a particular feature, structure, and/or characteristic included in at least one implementation of the invention. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1 is a block diagram of a system that includes a memory cell array, in accordance with an embodiment.

FIG. 2 is an 3D cross-sectional diagram of an array of memory cells with a patterned layer of storage material and a separate layer of selector material.

FIG. 3A is a cross-sectional diagram of an array of memory cells with an unpatterned layer of storage material, in accordance with an embodiment.

FIG. 3B is a cross-sectional diagram of the array of memory cells of FIG. 3A when viewed from another direction, in accordance with an embodiment.

FIG. 4 is a 3D diagram of an array of memory cells with an unpatterned layer of storage material, in accordance with an embodiment.

FIG. 5 is a cross-sectional diagram of an array of memory cells with an unpatterned layer of storage material and electrodes patterned into conductive lines, in accordance with an embodiment.

FIG. 6 is a cross-sectional diagram of an array of memory cells with an unpatterned layer of storage material and electrodes patterned into conductive dots, in accordance with an embodiment.

FIG. 7 is a flow diagram of a method of forming an array of memory cells with unpatterned storage material, in accordance with an embodiment.

FIGS. 8A-8C, 9A-9C, 10A-10C, 11A-11C, 12A-12C, 13A-13C, and 14A-14C illustrate views of a stack of materials, including an unpatterned layer of storage material, during formation of an array of memory cells, in accordance with an embodiment.

FIG. 15 is a block diagram of exemplary processing equipment for fabricating a memory cell array in accordance with embodiments described herein.

FIG. 16 is a block diagram of an embodiment of a computing system in which a memory module with an unpatterned storage material can be implemented.

FIG. 17 is a block diagram of an embodiment of a mobile device in which a memory module with unpatterned storage material can be implemented.

Descriptions of certain details and implementations follow, including a description of the figures, which may depict some or all of the embodiments described below, as well as discuss other potential embodiments or implementations of the inventive concepts presented herein.

### DETAILED DESCRIPTION

As mentioned briefly above, there is demand for memory devices that can be scaled smaller than traditional memory devices. One memory technology that has the potential to scale smaller than traditional memory devices is three-dimensional (3D) cross-point memory.

Some 3D cross-point devices include a stack of materials including a selector material, a storage material, and conductive layers, which are patterned to form an array of memory cells with conductive wordlines and bitlines. Patterning the stack results in “cross-points.” A cross-point is an intersection between a bitline, a wordline, and active material(s) (e.g., the selector and/or storage material). The storage material (or memory material) is capable of storing data. The selector material enables accessing a single bit in the array.

Another variation of a 3D cross-point device is a “self-selector” memory device. A self-selector memory device includes a single material that functions as both the selector and storage material. In one such example, a self-selector memory device does not include a separate selector, but instead includes a single layer of material that enables both storage and selection.

Typically, regardless of whether a 3D cross-point device includes a single layer of active material or multiple layers of active materials, definition of the individual memory cells traditionally involves patterning the active materials. For example, definition of the individual memory cells in an array involves patterning the storage material to separate the individual memory cells from one another. However, etching the storage material and/or the selector material can damage the storage elements. Furthermore, 3D cross-point devices that include a separate selector layer can be susceptible to interdiffusion of elements between the storage and selector layers during etch. Accordingly, the manufacturing process can require the use of sealing layers during cell definition to avoid interdiffusion. Thus, 3D cross-point manufacturing processes can include many deposition and etch operations, which can result in significant manufacturing complexity and cost.

In contrast to existing memory technologies that include a patterned storage material, in one embodiment, an array of memory cells includes a single layer of unpatterned material to form both the selector and storage element. The single layer of storage material is unpatterned in regions between the memory cells of the array. A region of storage material that is “unpatterned” or “nonpatterned” is a layer which has not been subject to patterning such as etching. Thus, the risk of interdiffusion of elements and damage to the memory cells can be significantly reduced or eliminated.

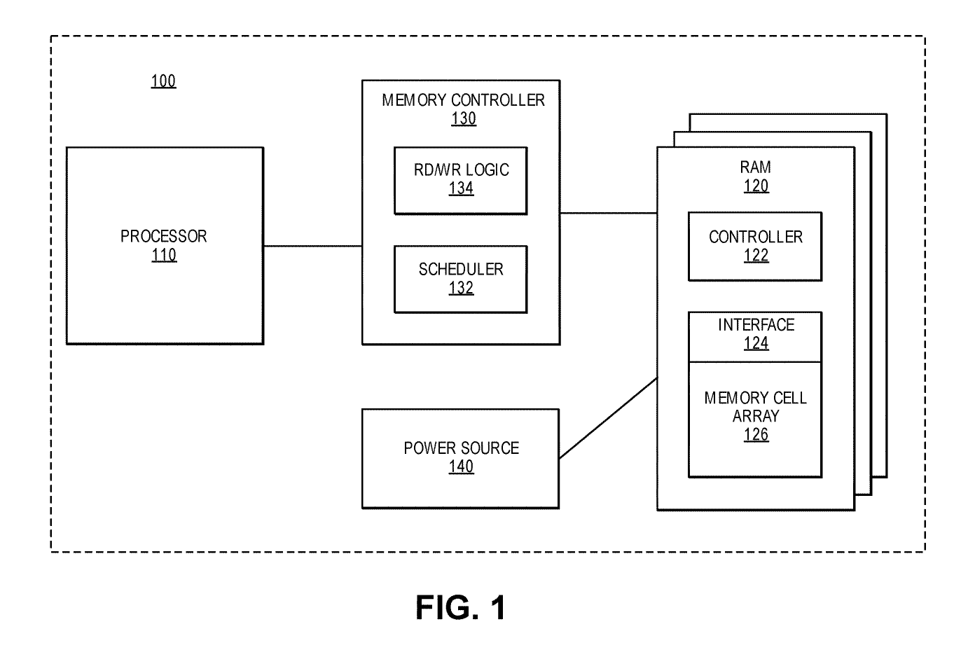

FIG. 1 is a block diagram of a system that includes a memory cell array, in accordance with an embodiment.

System 100 includes components of a memory subsystem having random access memory (RAM) 120 to store and provide data in response to operations of processor 110. System 100 receives memory access requests from a host or a processor 110, which is processing logic that executes operations based on data stored in RAM 120 or generates data to store in RAM 120. Processor 110 can be or include a host processor, central processing unit (CPU), microcontroller or microprocessor, graphics processor, peripheral processor, application specific processor, or other processor, and can be single core or multicore.

System 100 includes memory controller 130, which represents logic to interface with RAM 120 and manage access to data stored in the memory. In one embodiment, memory controller 130 is integrated into the hardware of processor 110. In one embodiment, memory controller 130 is standalone hardware, separate from processor 110. Memory controller 130 can be a separate circuit on a substrate that includes the processor. Memory controller 130 can be a separate die or chip integrated on a common substrate with a processor die (e.g., as a system on a chip (SoC)). In one embodiment, memory controller 130 is an integrated memory controller (iMC) integrated as a circuit on the processor die. In one embodiment, at least some of RAM 120 can be included on an SoC with memory controller 130 and/or processor 110.

In one embodiment, memory controller 130 includes read/write logic 134, which includes hardware to interface with RAM 120. Logic 134 enables memory controller 130 to generate read and write commands to service requests for data access generated by the execution of instructions by processor 110. In one embodiment, memory controller 130 includes scheduler 132 to schedule the sending of access commands to RAM 120 based on known timing parameters for read and write access for RAM 120. Known timing parameters can be those that are preprogrammed or otherwise preconfigured into system 100. Such parameters can be stored in RAM 120 and accessed by memory controller 130. In one embodiment, at least some parameters are determined by synchronization procedures. The timing parameters can include the timing associated with write latency for RAM 120. The write latency for RAM 120 can depend on the type of memory technology. RAM 120 can be a memory with a layer of unpatterned storage material, as is described in further detail below. In one such embodiment, RAM 120 is a self-selecting memory. In one such embodiment, the write latency is determined by the time needed to reconfigure the internal state of the cell. In one embodiment, RAM 120 is a phase change memory. In one such embodiment, the phase change memory includes a phase change region made of a phase change material. A phase change material can be electrically switched between a generally amorphous and a generally crystalline state across the entire spectrum between completely amorphous and completely crystalline states. In one such embodiment, the write latency is determined by the time involved to change from an amorphous to crystalline state.

The memory resources or cachelines in RAM 120 are represented by memory device array 126, which can include an unpatterned storage material. In one embodiment, the unpatterned storage material has sufficient selection properties to also act as the selector. For example, in one embodiment, the storage material is capable of switching between two or more threshold stable states. For example, in one embodiment, the storage material is capable of switching between a “lower stable state” and a “higher stable state.” In one such embodiment, a lower stable state is a low threshold/high current state (e.g., a state in which the formation of a conductive path in a well-defined region of the material has occurred) and the higher stable state is a high threshold/low current state (e.g., a state in which the formation of a conductive path in a well-defined region of the material has not occurred). In one such embodiment, the lower threshold stable state of the storage material is higher than the de-selection bias of a memory cell. Thus, in one embodiment, memory device array 126 includes a single layer of storage material and does not include a separate layer of selector material. RAM 120 includes interface 124 (e.g., interface logic) to control the access to memory device array 126. Interface 124 can include decode logic, including logic to address specific rows or columns or bits of data. In one embodiment, interface 124 includes logic to control the amount of current provided to specific memory cells of memory device array 126. Thus, control over writing to memory device array 126 can occur through driver and/or other access logic of interface 124. Controller 122 represents an on-die controller on RAM 120 to control its internal operations to execute commands received from memory controller 130. For example, controller 122 can control any of timing, addressing, I/O (input/output) margining, scheduling, and error correction for RAM 120.

In one embodiment, controller 122 is configured to read and write memory device array 126 in accordance with any embodiment described herein. In one embodiment, controller 122 can differentiate between different logic-states as a consequence of the programming polarity of a memory cell. For example, in one embodiment, controller 122 can read a memory cell by applying a voltage drop via interface 124 to the memory cell to determine the state (e.g., a higher stable state or lower stable state) of the memory cell. In one embodiment, controller 122 performs a read operation by applying a voltage that is insufficient to trigger a change of state of the storage material when the storage material is in its higher stable state, but the controller 122 is able to drive current when the storage material is in its lower stable state.

In one embodiment, when controller 122 is to write to a memory cell, controller 122 applies a quick pulse to the memory cell to program the polarity of the memory cell. In one such embodiment, programming in forward polarity will put the cell in one state (e.g., a lower threshold state) and programming in reverse polarity will put the cell in the other state (e.g., a higher threshold state). For example, in one embodiment, controller 122 applies a pulse in one polarity (e.g., bitline positive and wordline negative) to write a value (e.g., a ‘1’) or in the other polarity (e.g., bitline negative and wordline positive) to write another value (e.g., a ‘0’). In one such embodiment, controller 122 applies a pulse that is sufficient to trigger the storage material in its higher or lower stable state. System 100 includes power source 140, which can be a voltage source or regulator that provides power to RAM 120. Controller 122 and interface 124 can use the power available from power source 140 to apply a voltage drop to access a memory cell of array 126.

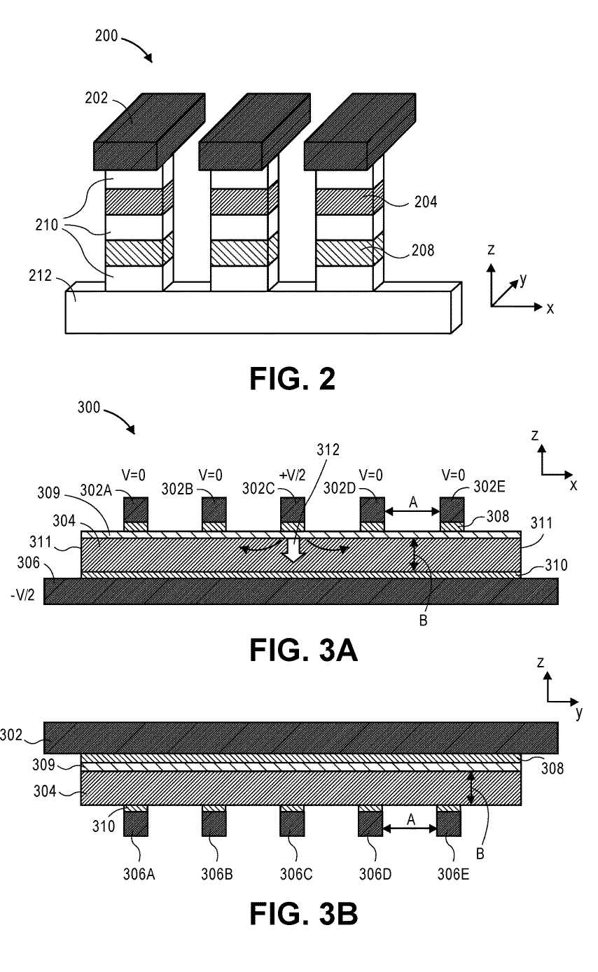

FIG. 2 is a 3D cross-sectional diagram of an array of memory cells with a patterned layer of storage material and a separate layer of selector material. Array 200 is an example of memory cells that include both a storage material and a selector material that is different than the storage material. For example, array 200 includes a patterned layer of selector material 208 and a patterned layer of storage material 204. Array 200 also includes layers of patterned conductive material 210 to form electrodes and patterned layers of conductive material to form conductive bitlines 202 and conductive wordlines 212, respectively. The electrodes are disposed in between the active materials 204, 208 and the conductive bitlines 202 and conductive wordlines 212. The patterned layer of selector material 208 forms selector elements that enable accessing only one cell of array 200 of memory cells. The patterned storage material 204 enables storage of information in accordance with an algorithm.

In the example illustrated in FIG. 2, both the selector material 208 and the storage material 204 are patterned. As illustrated, the cell stack of the array 200 is patterned in both the x and y directions using for example, an etching process. The etching process exposes the memory and selection elements to etch chemistries at the wordline and/or bitline definitions. The selector material 208 and the storage material 204 can have delicate stoichiometry, and thus the etch chemistries can damage the memory elements during etch of the selector and/or memory elements. Additionally, as mentioned briefly above, the etch process can cause interdiffusion of elements between the selector material 208 and the storage material 204. Accordingly, formation of the array 200 of memory cells can involve many deposition and etch operations, which can result in significant cost and complexity.

In contrast, FIGS. 3A and 3B are cross-sectional diagrams of an array of memory cells with an unpatterned layer of storage material, in accordance with an embodiment. FIGS. 3A and 3B illustrate the same array 300 of memory cells from different perspectives, in accordance with an embodiment. Array 300 includes a layer of storage material 304 to store information. Unlike array 200 of FIG. 2, array 300 of FIGS. 3A and 3B does not include a separate layer of selector material. Instead, according to one embodiment, storage material 304 acts as both the storage element and the selector element. In one such embodiment, the storage material of a given memory cell includes a self-selecting material to select that given memory cell and store data. In one embodiment, storage material 304 can store information by the formation of a conductive path in a well-defined region of the material or by the migration of specific ions towards the electrodes or, by the rearrangement of some atomic species inside the material. The storage material 304 can include, for example, chalcogenide materials such as Te—Se alloys, As—Se alloys, Ge—Te alloys, As—Se—Te alloys, Ge—As—Se alloys, Te—As—Ge alloys, Si—Ge—As—Se alloys, Si—Te—As—Ge alloys, or other material capable of functioning as both a storage element and a selector.

Also in contrast to storage material 204 of FIG. 2, layer of storage material 304 is unpatterned in regions between adjacent memory cells of the array. Thus, in one embodiment, storage material 304 lacks physical patterning to distinguish individual memory cells. For example, as illustrated in FIGS. 3A and 3B, an entire interior region of the layer of storage material 304 is unpatterned, and the layer of storage material 304 is only patterned at its periphery 311. Thus, the memory cells of array 300 are less likely to experience damage during the fabrication process than the memory cells of array 200 of FIG. 2.

Array 300 includes bitlines 302A-302E (302) and wordlines 306A-306E (306). In one embodiment, bitlines 302 and wordlines 306 are lines of conductive material. For example, bitlines 302 and wordlines 306 can include one or more metals including: Al, Cu, Ni, Cr, Co, Ru, Rh, Pd, Ag, Pt, Au, Ir, Ta, and W; conductive metal nitrides including TiN, TaN, WN, and TaCN; conductive metal silicides including tantalum silicides, tungsten silicides, nickel silicides, cobalt silicides and titanium silicides; conductive metal silicide nitrides including TiSiN and WSiN; conductive metal carbide nitrides including TiCN and WCN, or any other suitable electrically conductive material. FIG. 3A illustrates a cross-section along a wordline, and thus only a single wordline is visible. However, wordlines 306 can have a similar pattern as the bitlines, but in a different direction. For example, FIG. 3B illustrates a cross-section along a bitline, in accordance with an embodiment. As illustrated in FIG. 3B, wordlines 306 have a similar pattern as bitlines 302, but in a different direction. In one embodiment, wordlines 306 are orthogonal relative to bitlines 302.

In one embodiment, conductive electrodes 308 are disposed between bitlines 302 and storage material 304. Similarly, conductive electrodes 310 are disposed between storage material 304 and wordlines 306. In one embodiment, wordlines 306 are in electrical contact with conductive electrodes 310, and bitlines 302 are in electrical contact with conductive electrodes 308. Materials or layers that are in electrical contact are coupled to enable electrical conduction between the materials or layers, and can be in direct contact or separated by one or more layers that do not significantly interfere with electrical conduction. Conductive electrodes 308, 310 can be in direct contact with bitlines 302 and wordlines 306, respectively, or array 300 can include one or more layers between conductive electrodes 308, 310 and bitlines 302 and wordlines 306, respectively. Materials or layers that are in direct contact have surfaces that are directly adjacent to each other without an intervening layer.

Similarly, conductive electrodes 308, 310 can be in direct contact with the storage material 304, or the array 300 can include one or more layers between conductive electrodes 308, 310 and storage material 304. For example, in one embodiment, array 300 includes a thin dielectric layer between the storage material 304 and conductive electrodes 308. In one such embodiment, a thin dielectric material 309 can protect the underlying storage material 304 during the definition of bitlines 302. In one embodiment, thin dielectric material 309 is a thin layer of dielectric material that extends across the surface of storage material 304, and can thus protect storage material 304 from damage during an etch process. For example, in one embodiment, an etch process for defining bitlines 302 can stop at or on the dielectric layer 309 without touching the underlying storage material 304. In another such embodiment, the etch process for defining bitlines 302 can partially or fully etch the dielectric layer 309, but stop before reaching storage material 304. Thus, after etching, thin dielectric layer 309 can be non-etched, partially etched, or fully etched in regions between adjacent conductive electrodes 308, in accordance with embodiments.

In one embodiment with a thin dielectric layer 309 between the storage material 304 and conductive electrodes 308, thin dielectric layer 309 is thin enough so that the dielectric layer 309 does not interfere with the vertical path of current in the memory cells. For example, in one embodiment, the thin dielectric layer 309 is in the range of 0.5-5 nm, or another thickness that does not interfere with the operation of the memory cells. In one such embodiment, the thin dielectric layer can be aluminum oxide, zirconium oxide, hafnium oxide, silicon oxide, silicon nitride, or another suitable dielectric material that is sufficiently resilient to the etching chemistries and that does not significantly interfere with conduction in the memory cells.

Referring again to FIGS. 3A and 3B, in one embodiment, a given memory cell of the array is located where one of the conductive electrodes 308 overlaps one of the conductive electrodes 310. In one embodiment, storage material 304 is between conductive electrodes 308 and conductive electrodes 310, and the electrodes overlap if there is conductive electrode material in the same line along the z-axis, as illustrated in FIGS. 3A and 3B. The term “overlap” is not limiting in terms of orientation; therefore, conductive electrode 308 could be said to overlap conductive electrode 310, or vice versa. Note that although FIGS. 3A and 3B, as well as some of the other figures that follow, depict x-, y-, and z-axes for ease of reference, embodiments are not limited to being defined according to a specific coordinate system.

Thus, in one embodiment, the memory cells of array 300 are defined in part by the locations of conductive electrodes 308, 310. As discussed above, unlike conventional memory cells, in one embodiment, memory cells are not defined by a pattern in storage material 304. In one embodiment, storage material 304 is unpatterned in regions between adjacent memory cells of array 300.

In one embodiment, spacing or pitch of electrodes, bitlines, and/or wordlines can enable selection of a memory cell. In one such embodiment, the bitlines and/or wordlines are spaced sufficiently far apart to enable access to a single memory cell. In one embodiment, sufficient spacing between adjacent bitlines and/or wordlines can result in a sufficiently greater bias in the vertical direction of a given memory cell to favor conduction through the given memory cell, thus enabling selection of that cell. For example, in an embodiment with a self-selecting memory such as described above with respect to FIG. 1, sufficient spacing between adjacent wordlines and/or bitlines can enable determining and changing the polarity of the storage material of a single memory cell without changing the polarity of the storage material of neighboring memory cells. In an example with a phase-change memory, sufficient spacing between adjacent wordlines and/or bitlines can enable determining and changing the phase of the storage material of a single memory cell without changing the phase of the storage material of neighboring memory cells.

In one embodiment, the spacing or distance A between adjacent bitlines 302 is greater than a thickness B of storage material 304. In one such embodiment, the spacing or distance between adjacent wordlines 306 is also (or alternatively) greater than B. FIG. 3A illustrates the distance A between adjacent bitlines 302. FIG. 3B illustrates the distance A between adjacent wordlines 306. In one example, the width of the bitlines and/or wordlines is approximately 15 nm and the spacing A is 25 nm. However, according to one embodiment, line width can be less than or greater than 15 nm and the spacing A can be less than or greater than 25 nm as long as the dimensions enable selection of a single memory cell. In one embodiment, the thickness B of storage material 1002 is between 10-40 nm. However, the thickness B can be less than 10 nm or greater than 40 nm as long as the dimensions enable selection of a single memory cell and storage of data.

According to one embodiment, the spacing and dimensions of the bitlines, wordlines, and storage material can affect the voltage at which the array 300 can operate. FIG. 3A illustrates one example of an array that uses an operating voltage where A is greater than B, in accordance with an embodiment. In FIG. 3A, a voltage of +V/2 is applied to conductive bitline 302C. Conductive bitlines 302A, 302B, 302D, and 302E are at a voltage of 0 (e.g., grounded). Thus, conductive bitline 302C is selected, and conductive bitlines 302A, 302B, 302D, and 302E are not selected. A voltage of −V/2 is applied to the selected wordline 306. Although other conductive wordlines are not illustrated in this example, the conductive wordlines that are not selected would be at a voltage of 0, in accordance with an embodiment. Thus, in the illustrated example, there is a higher bias drop between the selected bitline 302C and the selected wordline 306 than between the unselected bitlines 302A, 302B, 302D, 302E and the selected wordline 306. For example, there is a voltage drop of V between the selected bitline 302C and the selected wordline 306, while the voltage drop between the unselected bitlines 302A, 302B, 302D, 302E and the selected wordline is less than V/2. Accordingly, the preference is for current to flow along the vertical direction (e.g., along the z-axis) at the selected bitline 302C as opposed to in the horizontal direction (e.g., along the x-axis), as shown by arrow 312. In one embodiment, although the storage material 304 of the memory cells of array 300 is not physically patterned, the cells are effectively electrically patterned during operation.

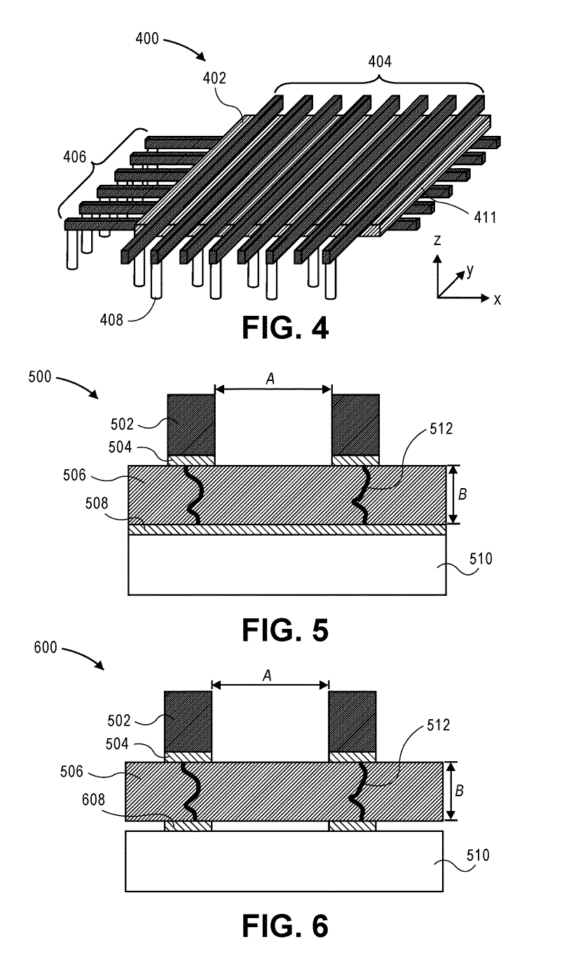

FIG. 4 is a 3D diagram of an array of memory cells with an unpatterned layer of storage material, in accordance with an embodiment. Array 400 is an example of an array such as array 300 of FIGS. 3A and 3B when viewed from a greater distance. Array 400 of memory cells includes layer of storage material 402 between a plurality of conductive bitlines 404 and conductive wordlines 406. As mentioned above with respect to FIGS. 3A and 3B, in one embodiment, layer of storage material 402 is unpatterned at its interior where the memory cells are located. However, layer of storage material 402 is roughly cut or patterned at its periphery 411. Cutting or etching the storage material at the edge of the array can enable coupling the bitlines and wordlines to conductive contacts. In one embodiment, because only a large square (or other shape) of material is patterned, the lithography process can employ a mask with relatively large (e.g., non-critical) dimensions.

The exposed bitlines, wordlines, and/or electrodes at the periphery of the storage material 402 can couple with contacts such as a plurality of vias 408 (e.g., through-silicon vias (TSVs)). A via is an electrical connection path that passes through the plane of one or more layers of an electronic circuit. In one embodiment, vias 408 run orthogonal (perpendicular) to the conductive bitlines 404 and conductive wordlines 406. For example, as illustrated in FIG. 4, an axis along the length of the via is orthogonal relative to conductive bitlines 404 and conductive wordlines 406. In one embodiment, a given via is in electrical contact with one of conductive bitlines 404 or conductive wordlines 406.

FIGS. 5 and 6 are cross-sectional diagrams of arrays of memory cells with different patterned electrode layers, in accordance with embodiments.

FIG. 5 is a cross-sectional diagram of an array of memory cells with electrodes patterned into conductive lines, in accordance with an embodiment. Array 500 of memory cells includes a layer of unpatterned storage material 506 disposed between conductive electrodes 504 and 508. Conductive electrodes 508 are disposed over conductive wordlines 510. A layer that is disposed “over” a second layer can be on or adjacent to the second layer, or can be separated from the second layer by one or more intermediate layers. Furthermore, a layer that is “over” a second layer is not limited in terms of orientation or method of manufacture; therefore, if a layer is over a second layer, the second layer can be referred to as being over the first layer when viewed from another perspective. Referring again to FIG. 5, conductive bitlines 502 are disposed over conductive electrodes 504. The lines 512 illustrate an area of storage material 506 in which conduction occurs when accessing a selected memory cell. According to one embodiment, conductive electrodes 504 and 508 are conductive lines or strips that are parallel with conductive bitlines 502 and conductive wordlines 510, respectively. In one such embodiment, the conductive electrode lines are continuous between memory cells. The conductive electrode lines are separated (e.g., separated by a filler material, or other technique for separating the lines of electrodes).

Similarly, FIG. 6 is a cross-sectional diagram of an array of memory cells, but with conductive electrodes that are patterned into dots, in accordance with an embodiment. Like array 500, array 600 of memory cells includes a layer of unpatterned storage material 506 disposed between conductive electrodes 604 and 608. Also like array 500, array 600 includes conductive bitlines 502 and conductive wordlines 510. However, in the embodiment illustrated in FIG. 6, conductive electrodes 604 and 608 are patterned lines of dots aligned with conductive bitlines 502 and conductive wordlines 510, respectively. In one embodiment, the dots are disposed in lines that are parallel to conductive bitlines 502 and conductive wordlines 510, respectively. The dots can have a shape with rounded, irregular, or straight edges (e.g., square, rectangular, or other shape). According to one embodiment, the location of a given dot is aligned with a memory cell of the array 600. For example, the dots are located at the intersections of conductive bitlines 502 and conductive wordlines 510. In one embodiment, a memory array with conductive dots for electrodes can achieve better confinement of the electric field and current to a particular cell than a memory array with conductive lines for electrodes. However, implementing a memory array with dots for electrodes can involve more processing (e.g., additional masking and patterning) than a memory array with lines for electrodes.

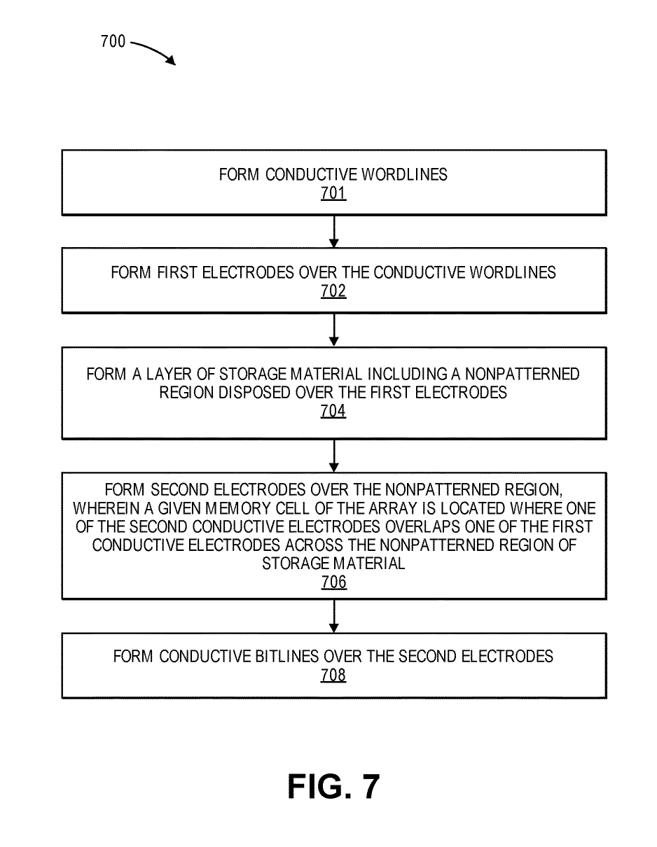

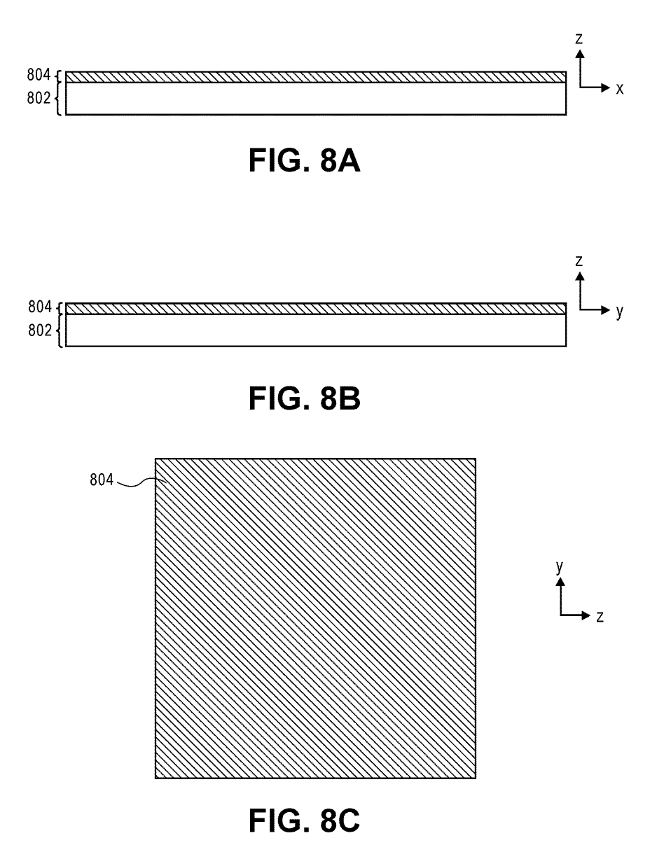

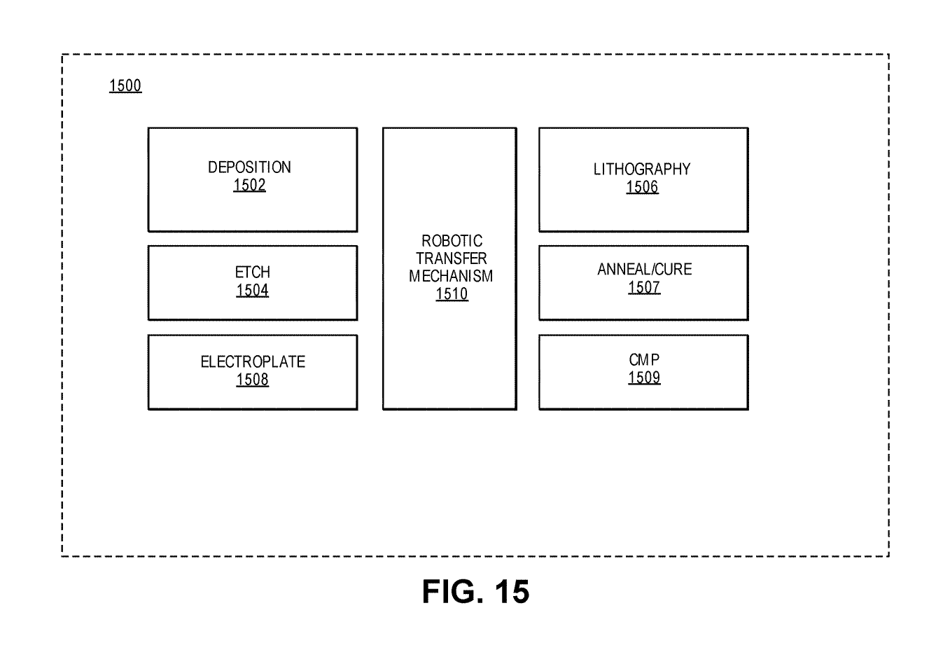

FIG. 7 is a flow diagram of an embodiment of a method of forming an array of memory cells, in accordance with an embodiment. Process 700 of FIG. 7 can be employed to form an array of memory cells such as array 400 of FIG. 4 or array 500 of FIG. 5, for example. FIGS. 8A-8C, 9A-9C, 10A-10C, 11A-11C, 12A-12C, 13A-13C, 14A-14C, 15A-15C, 16A-16C, and 17A-17C illustrate views of a stack of materials during formation of an array of memory cells, including views corresponding to the operations of process 700 of FIG. 7, in accordance with embodiments. The operations of process 700 can be performed by processing equipment capable of performing techniques such as deposition, lithography, and etching. FIG. 15, described below, illustrates an example of processing equipment for performing the operations of process 700.

Referring again to FIG. 7, in one embodiment, process 700 involves forming conductive word lines, 701. Process 700 also involves forming conductive electrodes over the conductive wordlines, 702. In one embodiment, forming conductive wordlines and an electrode layer over the conductive wordlines involves depositing conductive layers and patterning the conductive layers into wordlines and electrodes. FIGS. 8A-8C illustrate an example of conductive layers prior to patterning, in accordance with an embodiment. Note that FIGS. 8A-8C illustrate different perspectives of the same stack. FIGS. 8A and 8B depict cross-sections along different axes of the stack, and FIG. 8C depicts a top-down view of the stack. As illustrated in FIGS. 8A-8C, in one embodiment, processing equipment forms conductive wordline layer 802, and forms conductive electrode layer 804 over conductive wordline layer 802. As mentioned above, when processing equipment forms a layer “over” another layer, the stack can include one or more intervening layers. For example, although conductive electrode layer 804 is illustrated as being disposed directly on conductive wordline layer 802, the stack can include one or more layers (e.g., other conductive layers) between conductive electrode layer 804 and conductive wordline layer 802. Conductive electrode layer 804 can be composed of one or more conductive and/or semiconductive materials such as, for example: carbon (C), carbon nitride (CₓN_{y}); n-doped polysilicon and p-doped polysilicon; metals including, Al, Cu, Ni, Cr, Co, Ru, Rh, Pd, Ag, Pt, Au, Ir, Ta, and W; conductive metal nitrides including TiN, TaN, WN, and TaCN; conductive metal silicides including tantalum silicides, tungsten silicides, nickel silicides, cobalt silicides and titanium silicides; conductive metal silicides nitrides including TiSiN and WSiN; conductive metal carbide nitrides including TiCN and WCN; conductive metal oxides including RuO₂, or other suitable conductive materials. In one embodiment, conductive wordline layer can include any suitable metal including, for example, metals including, Al, Cu, Ni, Cr, Co, Ru, Rh, Pd, Ag, Pt, Au, Ir, Ta, and W; conductive metal nitrides including TiN, TaN, WN, and TaCN; conductive metal silicides including tantalum silicides, tungsten silicides, nickel silicides, cobalt silicides and titanium silicides; conductive metal silicides nitrides including TiSiN and WSiN; conductive metal carbide nitrides including TiCN and WCN, or another suitable electrically conductive material. Processing equipment can employ any suitable process for forming conductive layers such as electroplating, physical vapor deposition (PVD), chemical vapor deposition, or other process for forming conductive layers. After forming layers 802 and 804, the processing equipment can then pattern conductive electrode layer 804 and conductive wordline layer 802.

Patterning conductive electrode layer 804 and conductive wordline layer 802 can involve one or more processing steps such as deposition, lithography, etching, and/or other processing operations. For example, in one embodiment, processing equipment employs a multiple patterning process, such as self-aligned double patterning (SADP) or other multiple patterning process. In one embodiment, SADP employs a spacer to halve the pitch of an original pattern. For example, referring again to FIGS. 8A-8C, processing equipment can form a mask over conductive electrode layer 804. The mask can be, for example, a dielectric hard mask, or other suitable mask. Processing equipment can then form a photoresist pattern over the mask. Processing equipment can then form a spacer layer over the photoresist pattern. Processing equipment can then etch the spacer layer and photoresist pattern to create a new pattern (e.g., a “double pattern”) that has a pitch that is less than (e.g., half) the pitch of the photoresist pattern. The processing equipment can then transfer the new pattern to the mask. After patterning the mask with the new pattern, processing equipment can etch conductive layers 802 and 804 to form wordlines and electrodes. The above-described SADP process is one example of a patterning process, however, other embodiments can employ different processes to form of the wordlines and electrodes.

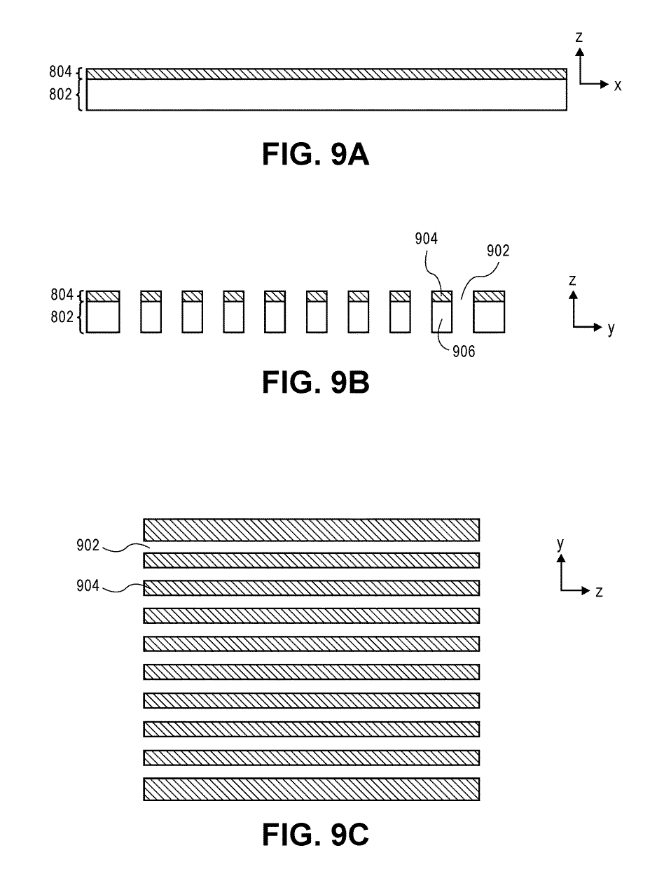

FIGS. 9A-9C illustrate an example of the stack in FIGS. 8A-8C after patterning layers 802 and 804 to form conductive wordlines 906 and conductive electrodes 904, in accordance with an embodiment. As illustrated in FIGS. 9A-9C, processing equipment patterns wordline layer 802 and conductive electrode layer 804 into conductive lines that are separated in the y-direction and continuous in the x-direction, in accordance with an embodiment. As described above with respect to FIGS. 5 and 6, processing equipment can pattern the electrode layer into lines or dots, in accordance with embodiments. FIGS. 9A-9C illustrate an example of electrodes patterned into lines. FIG. 6, which is discussed above, illustrates an example of electrodes patterned into dots. In one embodiment with line electrodes, processing equipment can pattern conductive electrode layer 804 into conductive electrode lines 904 parallel to conductive wordlines 906. Similarly, in one embodiment with dot electrodes, processing equipment can pattern conductive electrode layer 804 into dots of conductive material in lines that are parallel to conductive wordlines 906. As shown in FIGS. 9B and 9C, the electrode lines and the wordlines are separated by spaces or gaps 902, in accordance with an embodiment.

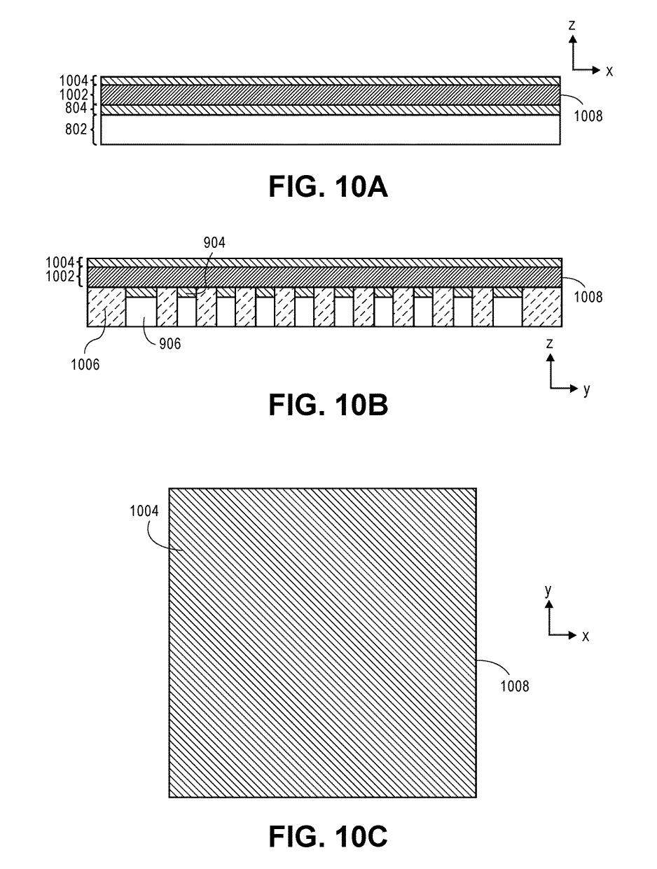

Turning again to FIG. 7, process 700 further involves forming a layer of storage material, 704. The layer of storage material includes an unpatterned region disposed over the conductive electrodes. Thus, in one embodiment, processing equipment deposits a layer of storage material, and does not pattern a region disposed over the conductive electrodes. Process 700 also involves forming another electrode layer over the unpatterned region of the layer of storage material, 706. FIGS. 10A-10C illustrate the stack of FIGS. 9A-9C after processing equipment deposits storage material 1002 and conductive electrode layer 1004, in accordance with an embodiment.

Prior to depositing storage material, processing equipment can perform other operations, in accordance with embodiments. For example, in one embodiment, and as illustrated in FIG. 10B, processing equipment deposits a filler material 1006 into the gaps between wordlines prior to depositing storage material 1002. Filler material 1006 can be, for example, a dielectric material such as silicon oxide (SiO₂) or other suitable dielectric. The filler material 1006 can fill the spaces between the wordlines to provide physical stability to the circuit without significantly interfering with the circuit's operation. In one such embodiment, forming filler material 1006 can involve deposition of a dielectric followed by a chemical mechanical planarization (CMP) process that stops on conductive electrode layer 804.

In one such embodiment, after filling the spaces between conductive wordlines with filler material 1006, processing equipment can deposit storage material 1002 over conductive electrodes 904 and filler material 1006, as illustrated in FIGS. 10A-10C. As discussed above, in one embodiment, the thickness of layer of storage material 1002 is dependent on the distance between conductive wordlines 906. For example, in one embodiment, processing equipment deposits a layer of storage material 1002 that has a thickness that is less than the distance between conductive wordlines 906. In one such embodiment, sufficient distance between conductive wordlines 906 relative to the thickness of storage material 1002 enables selection of a single bit without requiring a separate selector material. After depositing storage material 1002, in one embodiment, processing equipment forms conductive electrode layer 1004, as illustrated in FIGS. 10A-10C. Conductive electrode layer 1004 can be composed of the same or similar materials as conductive electrode layer 804 discussed above. Processing equipment can employ any suitable deposition technique to deposit storage material 1002, conductive electrode layer 1004, and/or filler material 1006. For example, processing equipment can employ chemical vapor deposition (CVD), atomic layer deposition (ALD), physical vapor deposition (PVD) such as physical sputtering, plasma-enhanced chemical vapor deposition (PECVD), hybrid physical chemical vapor deposition (HPCVD), or other deposition techniques.

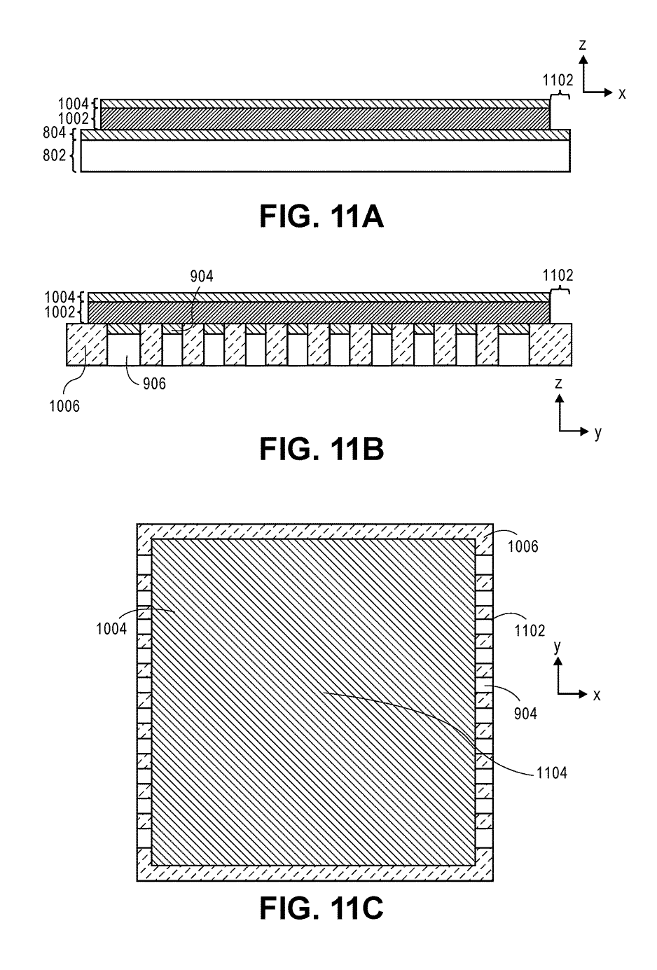

In one embodiment, after depositing storage material 1002, processing equipment etches storage material 1002 at its periphery 1008, but without etching storage material 1002 at its interior where the memory cells are located. FIGS. 11A-11C illustrates the stack of FIGS. 10A-10C after etching storage material 1002 and conductive electrode layer 1004, in accordance with an embodiment. Etching storage material 1002 at its periphery 1008 can involve, for example, depositing a mask (e.g., a photo-resist material) over conductive electrode layer 1004 and storage material 1002. In one embodiment, processing equipment uses a mask with relatively large (e.g., non-critical dimensions) to etch storage material 1002 into a relatively large slab (e.g., square or other suitable shape) of storage material. In one such embodiment, prior to etching, a periphery of conductive electrode layer 1004 is exposed beyond the edges of the mask. Processing equipment can then etch conductive electrode layer 1004 and storage material 1002 at the exposed periphery. Processing equipment can use any suitable etch technique such as wet etch or dry etch. In one embodiment, the etching process stops at conductive electrode layer 804.

Thus, in one embodiment, the etching process exposes a periphery 1102 of conductive electrode layer 804, as illustrated in FIGS. 11A-11C. Exposing conductive electrode layer 804 at its periphery can enable coupling of electrodes to electrical connectors such as pads, pins, vias, traces and/or other suitable contact structures. Unlike existing memory technologies, in one embodiment, storage material 1002 is only patterned at its periphery (e.g., to enable coupling to connectors), and its entire interior 1104 is unpatterned. Thus, storage material 1002 is unpatterned in the area where memory cells are defined and in between adjacent memory cells in accordance with an embodiment, as illustrated in FIGS. 11A-11C.

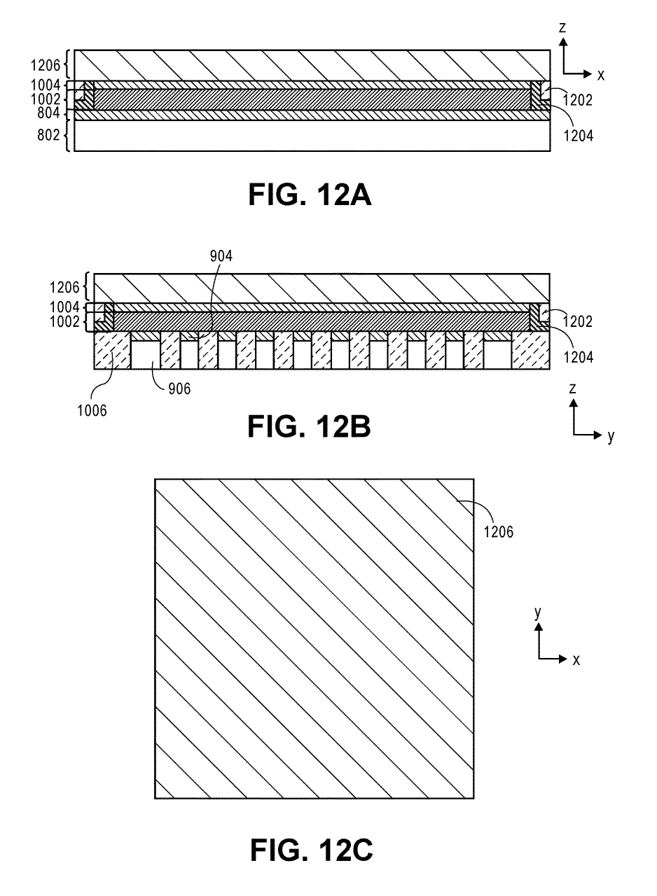

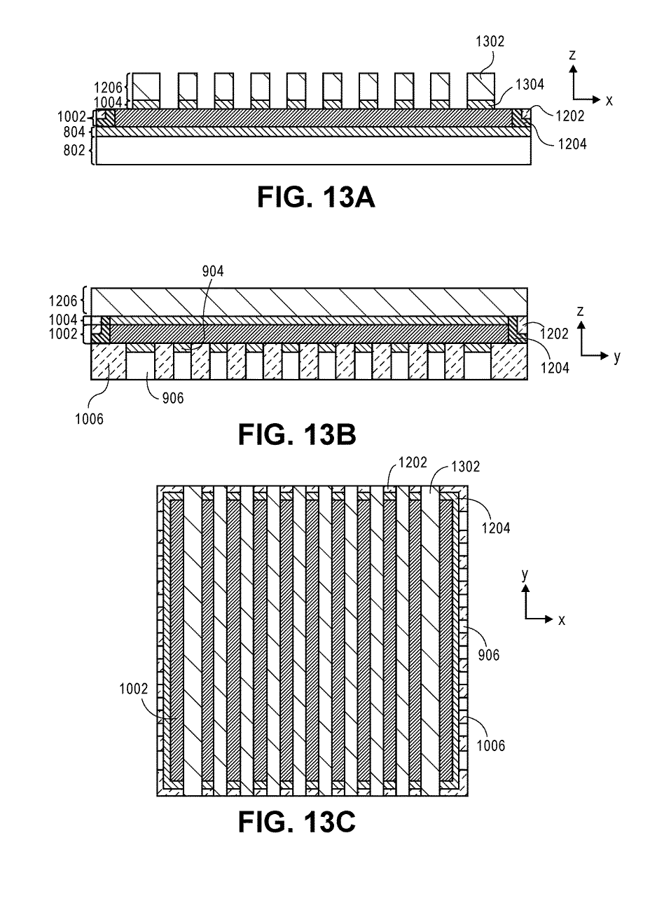

Turning again to FIG. 7, in one embodiment, after patterning storage material 1002 and conductive electrode layer 1004, processing equipment forms conductive bitlines, 708. In one embodiment, forming conductive bitlines involves deposition and patterning of one or more layers, as described below with respect to FIGS. 12A-12C and 13A-13C. FIGS. 12A-12C illustrate the stack of FIGS. 11A-11C after depositing conductive bitline layer 1206 as well as a sealing material 1204 and filler material 1202.

As illustrated in FIGS. 12A-12C, in one embodiment, prior to depositing conductive bitline layer 1206, processing equipment can deposit sealing material 1204 and filler material 1202. In one embodiment, sealing material can be, for example: silicon oxides, silicon nitrides, silicon oxynitrides, other oxides (such as alumina, hafnium oxides, titanium oxides, zirconium oxides), high-k materials, non-conductive nitrides, or other materials capable of acting as a sealing material. Sealing material 1204 can function as an insulator and/or chemical barrier to electrically insulate different structures and protect materials from contamination. In one such embodiment, prior to depositing conductive bitline layer 1206, processing equipment deposits sealing material 1204 over the entire electrode layer 1004. Processing equipment then deposits filler material 1202 over sealing material 1204. Filler material 1202 can be composed of the same or similar materials as filler material 1006, described above with respect to FIGS. 10A-10C. In one embodiment, processing equipment deposits sealing material 1204 and filler material 1202 as conformal layers. In one embodiment, the thickness of a conformal layer is approximately the same along the entire interface with the underlying layer. However, in other embodiments, sealing material 1204 and filler material 1202 can be nonconformal layers. After depositing sealing material 1204 and filler material 1202, in one embodiment, processing equipment performs a CMP operation on sealing material 1204 and filler material 1202, stopping on conductive electrode layer 1004. Thus, in one such embodiment, the previously exposed periphery 1102 of conductive electrodes 904 is filled with sealing material 1204 and filler material 1202, as illustrated in FIGS. 12A-12C.

In one embodiment, after deposition and planarization of sealing material 1204 and filler material 1202, processing equipment deposits conductive bitline layer 1206, as illustrated in FIGS. 12A-12C. Conductive bitline layer 1206 can be composed of the same or similar materials as the conductive wordlines, in accordance with embodiments. After forming conductive bitline layer 1206, in one embodiment, processing equipment patterns conductive bitline layer 1206 into conductive bitlines that are orthogonal to conductive wordlines 906 and patterns conductive electrode layer 1004 into conductive electrodes.

FIGS. 13A-13C illustrate the stack in FIGS. 12A-12C after patterning conductive bitline layer 1206 and conductive electrode layer 1004, in accordance with embodiments. In one embodiment, processing equipment patterns conductive bitline layer 1206 into conductive bitlines 1302. As illustrated in FIG. 13A, conductive bitlines 1302 are continuous in the x-direction and separated in the y-direction. In one embodiment, conductive bitlines 1302 are orthogonal to conductive wordlines 906, which is shown in the topdown view of FIG. 13C. Note that conductive wordlines 906 are illustrated in FIG. 13C for illustrative purposes, and may not actually be visible in a topdown view after patterning conductive bitlines 1302. In one embodiment, similar to the wordlines described with reference to FIGS. 9A-9C, processing equipment patterns conductive bitline layer 1206 into conductive bitlines 1302 that have a spacing that is greater than the thickness of the layer of storage material 1002. Processing equipment can pattern conductive bitline layer 1206 using the same or similar process steps employed to pattern conductive wordline layer 802 described with reference to FIGS. 8A-8C. For example, in one embodiment, processing equipment employs a multiple patterning process, such as self-aligned double patterning (SADP) or other multiple patterning process. However, other embodiments can employ different processes to form of conductive bitlines 1302 and conductive electrodes 1304.

As mentioned above, other embodiments can include other operations such as formation of additional and/or intervening layers. For example, in one embodiment, processing equipment forms a thin dielectric layer between storage material 1002 and conductive electrode layer 1004. Thus, in one such embodiment, prior to forming conductive electrode layer 1004, processing equipment forms a thin dielectric layer (not shown). In one such embodiment, the thin dielectric layer can be similar to or the same as the thin dielectric layer 309 of FIGS. 3A and 3B described above. In one such embodiment, when patterning conductive electrode layer 1004 and conductive bitline layer 1206, processing equipment etches conductive bitline layer 1206 and conductive electrode layer 1004, and stops etching at the dielectric layer before reaching storage material 1002. Thus, in one such embodiment, a dielectric layer can prevent damage to storage material 1002 during etch.

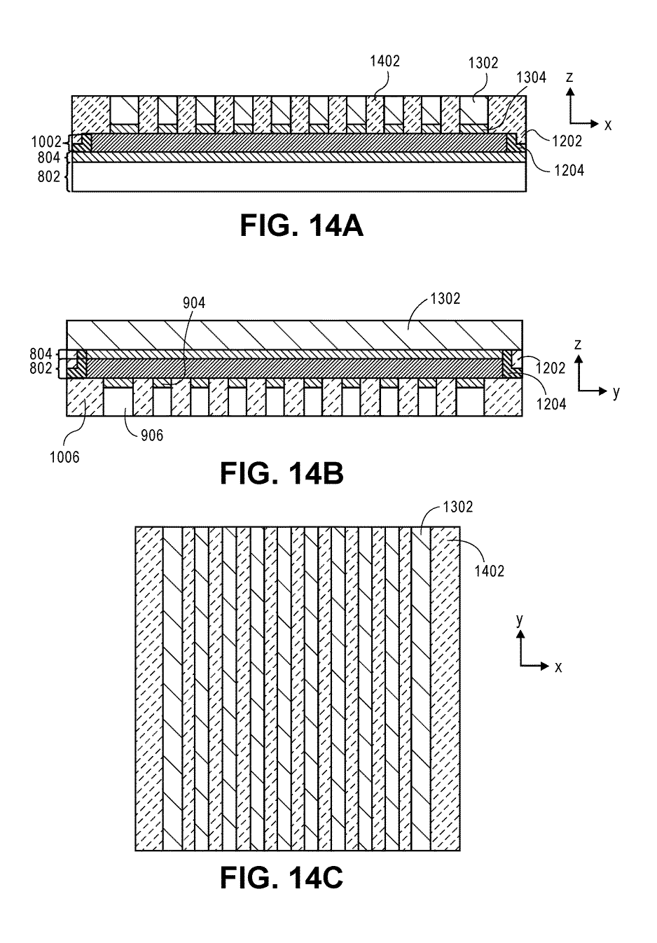

After forming bitlines 1302 as illustrated in FIGS. 13A-13C, processing equipment can perform additional operations, such as depositing a filler material between adjacent bitlines 1302. FIGS. 14A-14C illustrate the stack of FIGS. 13A-13C after depositing a filler material between conductive bitlines 1302, in accordance with embodiment. In one such embodiment, filler material 1402 can be the same, or a similar material as filler material 1202 described above with respect to FIGS. 12A-12C. For example, in one embodiment, filler material 1402 is a dielectric, such as filler material 1006 described above with respect to FIGS. 10A-10C. In one embodiment, processing equipment deposits filler material 1402 over and in between patterned conductive bitlines 1302, and then performs a CMP process to etch away the filler material to expose conductive bitlines 1302.

Thus, processing equipment can perform process 700 of FIG. 7 to form a memory cell array such as illustrated in FIGS. 14A-14C. In one embodiment, storage material 1002 is unpatterned in the regions where the memory cells are defined, which can reduce process complexity and risk of damage to the memory cells.

FIG. 15 is a block diagram of exemplary processing equipment for fabricating a memory cell array in accordance with embodiments described herein. Processing equipment 1500 can include tools to perform materials processing operations such as deposition, etching (e.g., wet or dry etching, laser etching, or other etch processes), ion implantation, chemical mechanical planarization (CMP), annealing, curing, cleaning, and/or other materials processing operations. As illustrated, processing equipment 1500 includes a deposition tool 1502, in accordance with embodiments. Although one deposition tool 1502 is illustrated, other embodiments can include more than one deposition tool. Deposition tool 1502 can include, for example, equipment to perform chemical vapor deposition (CVD), atomic layer deposition (ALD), physical vapor deposition (PVD) such as physical sputtering, plasma-enhanced chemical vapor deposition (PECVD), hybrid physical chemical vapor deposition (HPCVD), or other deposition techniques. Deposition tool 1502 can deposit one or more of the layers described herein to form a memory cell array. For example, deposition tool 1502 can deposit storage material 1002 of FIGS. 10A-10C. Processing equipment 1500 can also include an electroplating tool 1508 to form conductive layers via an electroplating or electrodeposition process.

Processing equipment 1500 also includes an etch tool or chamber 1504, for example, a wet or dry etch tool. Wet etching can involve, for example, immersing the substrate being processed in a wet etchant, or other wet etching technique. Dry etching can involve, for example, the removal of material by exposing the substrate to bombardment of ions (e.g., via a plasma of reactive gases) that dislodge portions of the material from surfaces of the substrate that are exposed to the ions. Although one etch tool 1504 is illustrated, other embodiments can include more than one etch tool. Etch tool 1504 can perform etching or patterning operations of methods described herein. For example, etch tool 1504 can pattern conductive electrode layer 804 of FIGS. 9A-9C to form conductive electrodes 904.

Processing equipment 1500 also includes lithography tool 1506. Lithography tool 1506 can use light to transfer a pattern from a photomask to a light-sensitive chemical “photoresist” on the substrate. Subsequent operations, such as chemical treatments, can then etch the pattern into the material under the photoresist, or enable deposition of a new material in the pattern. For example, lithography tool 1506 can form a patterned mask over conductive electrode layer 804 to create the lines seen in FIG. 9C. Processing equipment also includes an annealing and/or curing tool 1507. Annealing/curing tool 1507 can include a furnace or other heating mechanism to anneal or cure layers on a substrate.

Processing equipment also includes CMP tool 1509. CMP tool 1509 can perform chemical mechanical planarization operations by using, for example, a chemical slurry to planarize a surface of a substrate. For example, CMP tool 1509 can perform a CMP operation on the substrate after deposition of conformal layers of sealing and filler material to remove the sealing and filler material from the surface of conductive electrode layer 1004. In one such embodiment, after performing a CMP operation, sealing material 1204 and filler material 1202 remains on the sides of storage material 1002 and electrode layer 1004 as seen in FIGS. 12A-12C.

The tools of processing equipment can be combined into a single tool, can be separate tools. In another embodiment, some tools are combined while others are separate. Robotic transfer mechanisms 1510 can transfer the substrate or wafer being processed amongst tools.

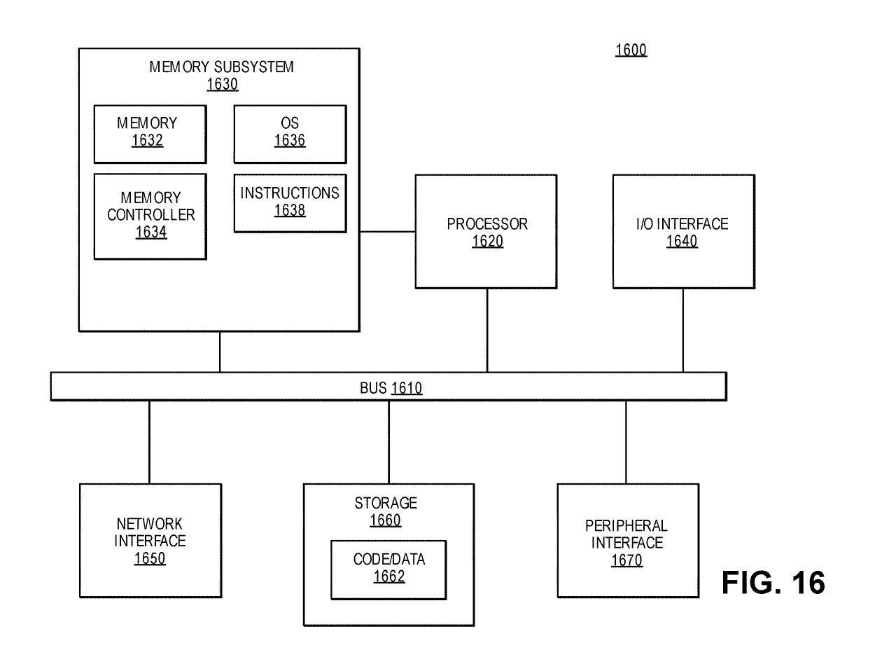

Processing equipment includes control logic to operate the equipment and control parameters of the process. In one embodiment, each tool includes its own control logic. The control logic can include hardware logic and/or software/firmware logic to control the processing. The equipment can be programmed or configured to perform certain operations in a certain order. For example, a manufacturing entity can configure processing equipment 1500 to perform operations on a wafer or substrate to form electronic circuits. The processing equipment can also include other components of a computer system, such one or more components of system 1600 of FIG. 16. For example, in one embodiment, processing equipment can include one or more displays and input devices for managing the processing equipment. A manufacturing entity typically operates the processing equipment.

FIG. 16 is a block diagram of an embodiment of a computing system in which a memory module with unpatterned storage elements can be implemented. System 1600 represents a computing device in accordance with any embodiment described herein, and can be a laptop computer, a desktop computer, a server, a gaming or entertainment control system, a scanner, copier, printer, routing or switching device, or other electronic device. System 1600 includes processor 1620, which provides processing, operation management, and execution of instructions for system 1600. Processor 1620 can include any type of microprocessor, central processing unit (CPU), processing core, or other processing hardware to provide processing for system 1600. Processor 1620 controls the overall operation of system 1600, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Memory subsystem 1630 represents the main memory of system 1600, and provides temporary storage for code to be executed by processor 1620, or data values to be used in executing a routine. Memory subsystem 1630 can include one or more memory devices such as read-only memory (ROM), flash memory, one or more varieties of random access memory (RAM), or other memory devices, or a combination of such devices. Memory subsystem 1630 stores and hosts, among other things, operating system (OS) 1636 to provide a software platform for execution of instructions in system 1600. Additionally, other instructions 1638 are stored and executed from memory subsystem 1630 to provide the logic and the processing of system 1600. OS 1636 and instructions 1638 are executed by processor 1620. Memory subsystem 1630 includes memory device 1632 where it stores data, instructions, programs, or other items. In one embodiment, memory subsystem includes memory controller 1634, which is a memory controller to generate and issue commands to memory device 1632. Memory device 1632 can include an array of memory cells with an unpatterned storage material as described herein. It will be understood that memory controller 1634 could be a physical part of processor 1620.

Processor 1620 and memory subsystem 1630 are coupled to bus/bus system 1610. Bus 1610 is an abstraction that represents any one or more separate physical buses, communication lines/interfaces, and/or point-to-point connections, connected by appropriate bridges, adapters, and/or controllers. Therefore, bus 1610 can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus (commonly referred to as “Firewire”). The buses of bus 1610 can also correspond to interfaces in network interface 1650.

System 1600 includes a power source to provide power to the components of system 1600. In one embodiment, the power source includes an AC to DC (alternating current to direct current) adapter to plug into a wall outlet. Such AC power can be renewable energy (e.g., solar power). In one embodiment, the power source includes only DC power, which can be provided by a DC power source, such as an external AC to DC converter. In one embodiment, the power source includes wireless charging hardware to charge via proximity to a charging field. In one embodiment, the power source can include an internal battery, AC-DC converter at least to receive alternating current and supply direct current, renewable energy source (e.g., solar power or motion based power), or the like.

System 1600 also includes one or more input/output (I/O) interface(s) 1640, network interface 1650, one or more internal mass storage device(s) 1660, and peripheral interface 1670 coupled to bus 1610. I/O interface 1640 can include one or more interface components through which a user interacts with system 1600 (e.g., video, audio, and/or alphanumeric interfacing). Network interface 1650 provides system 1600 the ability to communicate with remote devices (e.g., servers, other computing devices) over one or more networks. Network interface 1650 can include an Ethernet adapter, wireless interconnection components, USB (universal serial bus), or other wired or wireless standards-based or proprietary interfaces.

Storage 1660 can be or include any conventional medium for storing large amounts of data in a nonvolatile manner, such as one or more magnetic, solid state, or optical based disks, or a combination. Storage 1660 holds code or instructions and data 1662 in a persistent state (i.e., the value is retained despite interruption of power to system 1600). Storage 1660 can be generically considered to be a “memory,” although memory 1632 is the executing or operating memory to provide instructions to processor 1620. Whereas storage 1660 is nonvolatile, memory 1632 can include volatile memory (i.e., the value or state of the data is indeterminate if power is interrupted to system 1600).

Peripheral interface 1670 can include any hardware interface not specifically mentioned above. Peripherals refer generally to devices that connect dependently to system 1600. A dependent connection is one where system 1600 provides the software and/or hardware platform on which operation executes, and with which a user interacts.

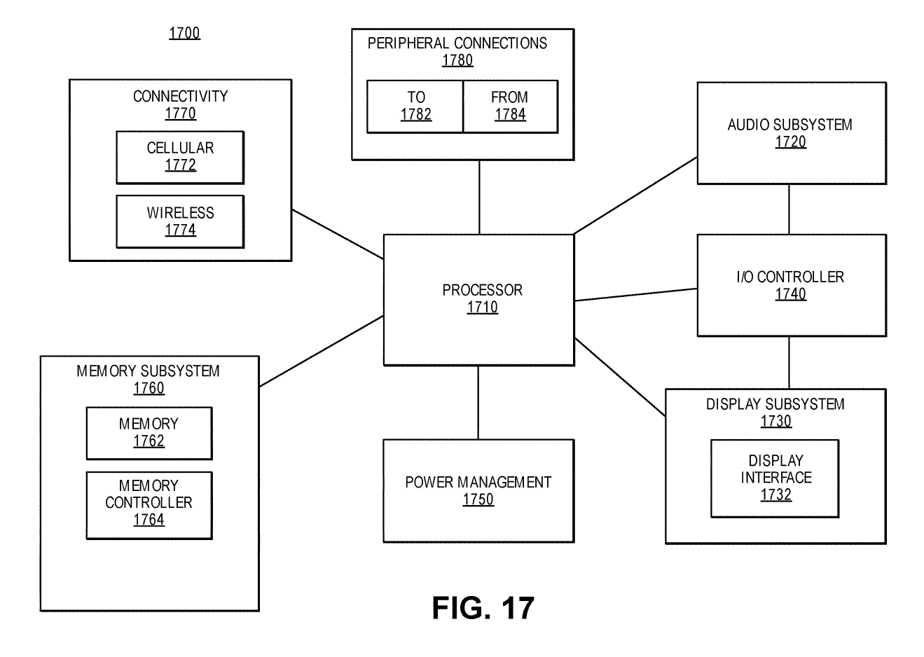

FIG. 17 is a block diagram of an embodiment of a mobile device in which a memory module with a layer of unpatterned storage material can be implemented. Device 1700 represents a mobile computing device, such as a computing tablet, a mobile phone or smartphone, a wireless-enabled e-reader, wearable computing device, or other mobile device. It will be understood that certain of the components are shown generally, and not all components of such a device are shown in device 1700.

Device 1700 includes processor 1710, which performs the primary processing operations of device 1700. Processor 1710 can include one or more physical devices, such as microprocessors, application processors, microcontrollers, programmable logic devices, or other processing means. The processing operations performed by processor 1710 include the execution of an operating platform or operating system on which applications and/or device functions are executed. The processing operations include operations related to I/O (input/output) with a human user or with other devices, operations related to power management, and/or operations related to connecting device 1700 to another device. The processing operations can also include operations related to audio I/O and/or display I/O.

In one embodiment, device 1700 includes audio subsystem 1720, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into device 1700, or connected to device 1700. In one embodiment, a user interacts with device 1700 by providing audio commands that are received and processed by processor 1710.

Display subsystem 1730 represents hardware (e.g., display devices) and software (e.g., drivers) components that provide a visual and/or tactile display for a user to interact with the computing device. Display subsystem 1730 includes display interface 1732, which includes the particular screen or hardware device used to provide a display to a user. In one embodiment, display interface 1732 includes logic separate from processor 1710 to perform at least some processing related to the display. In one embodiment, display subsystem 1730 includes a touchscreen device that provides both output and input to a user. In one embodiment, display subsystem 1730 includes a high definition (HD) display that provides an output to a user. High definition can refer to a display having a pixel density of approximately 100 pixels per inch (PPI) or greater, and can include formats such as full HD (e.g., 1080p), retina displays, 4K (ultra high definition or UHD), or others.

I/O controller 1740 represents hardware devices and software components related to interaction with a user. I/O controller 1740 can operate to manage hardware that is part of audio subsystem 1720 and/or display subsystem 1730. Additionally, I/O controller 1740 illustrates a connection point for additional devices that connect to device 1700 through which a user might interact with the system. For example, devices that can be attached to device 1700 might include microphone devices, speaker or stereo systems, video systems or other display device, keyboard or keypad devices, or other I/O devices for use with specific applications such as card readers or other devices.

As mentioned above, I/O controller 1740 can interact with audio subsystem 1720 and/or display subsystem 1730. For example, input through a microphone or other audio device can provide input or commands for one or more applications or functions of device 1700. Additionally, audio output can be provided instead of or in addition to display output. In another example, if display subsystem includes a touchscreen, the display device also acts as an input device, which can be at least partially managed by I/O controller 1740. There can also be additional buttons or switches on device 1700 to provide I/O functions managed by I/O controller 1740.

In one embodiment, I/O controller 1740 manages devices such as accelerometers, cameras, light sensors or other environmental sensors, gyroscopes, global positioning system (GPS), or other hardware that can be included in device 1700. The input can be part of direct user interaction, as well as providing environmental input to the system to influence its operations (such as filtering for noise, adjusting displays for brightness detection, applying a flash for a camera, or other features). In one embodiment, device 1700 includes power management 1750 that manages battery power usage, charging of the battery, and features related to power saving operation. In one embodiment, power management 1750 manages power from a power source, which provides power to the components of device 1700. In one embodiment, the power source includes an AC to DC (alternating current to direct current) adapter to plug into a wall outlet. Such AC power can be renewable energy (e.g., solar power). In one embodiment, the power source includes only DC power, which can be provided by a DC power source, such as an external AC to DC converter. In one embodiment, the power source includes wireless charging hardware to charge via proximity to a charging field. In one embodiment, the power source can include an internal battery or fuel cell source.

Memory subsystem 1760 includes memory device(s) 1762 for storing information in device 1700. Memory subsystem 1760 can include nonvolatile (state does not change if power to the memory device is interrupted) and/or volatile (state is indeterminate if power to the memory device is interrupted) memory devices. Memory devices 1762 can include an array of memory cells with an unpatterned storage material as described herein. Memory devices 1762 can store application data, user data, music, photos, documents, or other data, as well as system data (whether long-term or temporary) related to the execution of the applications and functions of device 1700. In one embodiment, memory subsystem 1760 includes memory controller 1764 (which could also be considered part of the control of device 1700, and could potentially be considered part of processor 1710). Memory controller 1764 includes a scheduler to generate and issue commands to memory device 1762.

Connectivity 1770 includes hardware devices (e.g., wireless and/or wired connectors and communication hardware) and software components (e.g., drivers, protocol stacks) to enable device 1700 to communicate with external devices. The external device could be separate devices, such as other computing devices, wireless access points or base stations, as well as peripherals such as headsets, printers, or other devices.

Connectivity 1770 can include multiple different types of connectivity. To generalize, device 1700 is illustrated with cellular connectivity 1772 and wireless connectivity 1774. Cellular connectivity 1772 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 1774 refers to wireless connectivity that is not cellular, and can include personal area networks (such as Bluetooth), local area networks (such as WiFi), and/or wide area networks (such as WiMax), or other wireless communication. Wireless communication refers to transfer of data through the use of modulated electromagnetic radiation through a non-solid medium. Wired communication occurs through a solid communication medium.

Peripheral connections 1780 include hardware interfaces and connectors, as well as software components (e.g., drivers, protocol stacks) to make peripheral connections. It will be understood that device 1700 could both be a peripheral device (“to” 1782) to other computing devices, as well as have peripheral devices (“from” 1784) connected to it. Device 1700 commonly has a “docking” connector to connect to other computing devices for purposes such as managing (e.g., downloading and/or uploading, changing, synchronizing) content on device 1700. Additionally, a docking connector can allow device 1700 to connect to certain peripherals that allow device 1700 to control content output, for example, to audiovisual or other systems.

In addition to a proprietary docking connector or other proprietary connection hardware, device 1700 can make peripheral connections 1780 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other type.

Device 1700 can be powered by a battery, wireless charging, a renewal energy source (e.g., solar power), or when connected to a wall outlet.

In one embodiment, a circuit includes an array of memory cells, and the array of memory cells includes first conductive electrodes. The array of memory cells also includes a layer of storage material including a nonpatterned region disposed over the first conductive electrodes. The array of memory cells also includes second conductive electrodes disposed over the nonpatterned region of the storage material. A given memory cell of the array is located where one of the second conductive electrodes overlaps one of the first conductive electrodes across the nonpatterned region of storage material.

In one embodiment, the array of memory cells also includes conductive wordlines in electrical contact with the first electrodes. In one embodiment, the spacing between adjacent conductive wordlines is greater than a thickness of the layer of storage material. In one embodiment, the first conductive electrodes include lines of conductive material parallel to the conductive wordlines. In one embodiment, the first conductive electrodes include dots of conductive material in lines parallel to the conductive wordlines.

In one embodiment, the array of memory cells includes conductive bitlines in electrical contact with the second electrodes, wherein the conductive bitlines are orthogonal to the conductive wordlines. In one embodiment, the spacing between adjacent conductive bitlines is greater than a thickness of the layer of storage material. In one embodiment, the second conductive electrodes comprise second lines of conductive material parallel to the conductive bitlines. In one embodiment, the second conductive electrodes include dots of conductive material in lines parallel to the conductive bitlines.

In one embodiment, the array of memory cells includes a plurality of vias, wherein a given via of the plurality of vias is in electrical contact with one of the conductive bitlines or wordlines, and wherein an axis along a length of the via is disposed orthogonal to the conductive bitlines and wordlines. In one embodiment, the layer of storage material comprises a layer of chalcogenide glass. In one embodiment, the array of memory cells includes a thin dielectric layer between the layer of storage material and the second electrodes. In one embodiment, the thin dielectric layer is partially etched in regions between adjacent second electrodes.

In one embodiment, the storage material of a given memory cell of the array includes a self-selecting material to select the given memory cell and store data. In one embodiment, the layer of storage material is patterned at its periphery and an entire interior region of the layer of storage material is nonpatterned. In one embodiment, the distance between adjacent conductive wordlines is approximately 25 nm and a width of one of the conductive wordlines is 15 nm. In one embodiment, the distance between the conductive bitlines is approximately 25 nm and a width of one of the conductive bitlines is 15 nm. In one embodiment, the thickness of the storage material is in a range of 10-40 nm.

In one embodiment, a system includes a processor and a memory communicatively coupled to the processor, the memory including an array of memory cells. The array of memory cells includes first conductive electrodes and a layer of storage material including a nonpatterned region disposed over the first conductive electrodes. The array of memory cells also includes second conductive electrodes disposed over the nonpatterned region of the storage material. A given memory cell of the array is located where one of the second conductive electrodes overlaps one of the first conductive electrodes across the nonpatterned region of storage material. The array of memory cells of the system can be in accordance with any of the arrays of memory cells described above. In one embodiment, the system further includes any of a display communicatively coupled to the processor, a network interface communicatively coupled to the processor, or a battery coupled to provide power to the system.

In one embodiment, a method of forming a circuit including an array of memory cells involves forming first conductive electrodes. The method further involves forming a layer of storage material including a nonpatterned region disposed over the first conductive electrodes. The method further involves forming second conductive electrodes over the nonpatterned region of the storage material. A given memory cell of the array is located where one of the second conductive electrodes overlaps one of the first conductive electrodes across the nonpatterned region of storage material.

In one embodiment, the method further involves forming conductive wordlines, wherein the first conductive electrodes are formed over the conductive wordlines. In one embodiment, the method further involves forming conductive bitlines over the second electrodes, wherein a distance between adjacent conductive bitlines and between adjacent conductive wordlines is greater than a thickness of the layer of storage material. In one embodiment, forming the second conductive electrodes involves depositing a second conductive electrode layer and patterning the second conductive electrode layer into conductive lines. In one embodiment, prior to depositing the second conductive electrode layer, the method involves forming a thin dielectric layer over the layer of storage material, wherein patterning the second conductive electrode layer includes etching the second conductive electrode layer and stopping etching before reaching the storage material.

In one embodiment, forming first electrodes involves depositing a conductive electrode layer over a conductive wordline layer, forming a patterned mask over the conductive electrode layer, and etching the conductive electrode layer and the conductive wordline layer into lines through gaps in the patterned mask.

In one embodiment, forming the second conductive electrodes involves depositing a conductive electrode layer over a conductive wordline layer, forming a patterned mask over the conductive electrode layer, and etching the conductive electrode layer into dots through gaps in the patterned mask. In one embodiment, forming the patterned mask involves depositing a photoresist material, etching the photoresist material to form a first pattern, depositing a spacer layer over the patterned photoresist material, and etching the spacer layer to form a second pattern having a smaller pitch than the first pattern.

In one embodiment, the method involves depositing a dielectric material between adjacent conductive wordlines. In one embodiment, the method involves patterning the storage material at its periphery to expose edges of the first electrodes. In one embodiment, patterning the storage material at its periphery involves depositing a photo-resist material over a second conductive electrode layer disposed over the storage material, wherein a periphery of the second conductive electrode layer is exposed beyond edges of the photo-resist material, etching the second conductive electrode layer and the storage material at the exposed periphery, and stopping etching at the first electrodes.

In one embodiment, the method further involves depositing one or more dielectric layers over the patterned second conductive electrode layer and an exposed periphery of the first electrodes, etching the one or more dielectric layers, and stopping etching at the patterned second conductive electrode layer.

In one embodiment, the method further involves forming a plurality of vias orthogonal to the conductive bitlines and wordlines, wherein the plurality of vias is to electrically contact one of the conductive bitlines or wordlines.

In one embodiment, forming the layer of storage material involves depositing a layer of chalcogenide glass over the first electrodes. In one embodiment, forming the conductive wordlines comprises patterning a conductive wordline layer into lines having a width of approximately 15 nm and spaced approximately 25 nm apart. In one embodiment, forming the conductive bitlines comprises patterning a conductive bitline layer into lines having a width of approximately 15 nm and spaced approximately 25 nm apart. In one embodiment, forming the layer of storage material comprises depositing the layer of storage material having a thickness in a range of 10-40 nm.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to the disclosed embodiments and implementations of the invention without departing from their scope. Therefore, the illustrations and examples herein should be construed in an illustrative, and not a restrictive sense. The scope of the invention should be measured solely by reference to the claims that follow.

1. A circuit including an array of memory cells, the array of memory cells comprising:
first conductive electrodes;
a layer of storage material including a nonpatterned region disposed over the first conductive electrodes; and
second conductive electrodes disposed over the nonpatterned region of the storage material;
wherein a given memory cell of the array is located where one of the second conductive electrodes overlaps one of the first conductive electrodes across the nonpatterned region of storage material.

2. The circuit of claim 1, further comprising:
conductive wordlines in electrical contact with the first electrodes.

3. The circuit of claim 2, wherein spacing between adjacent conductive wordlines is greater than a thickness of the layer of storage material.

4. The circuit of claim 2, wherein the first conductive electrodes comprise lines of conductive material parallel to the conductive wordlines.

5. The circuit of claim 2, wherein the first conductive electrodes comprise dots of conductive material in lines parallel to the conductive wordlines.

6. The circuit of claim 2, further comprising:
conductive bitlines in electrical contact with the second electrodes;
wherein the conductive bitlines are orthogonal to the conductive wordlines.

7. The circuit of claim 6, wherein spacing between adjacent conductive bitlines is greater than a thickness of the layer of storage material.

8. The circuit of claim 6, wherein the second conductive electrodes comprise second lines of conductive material parallel to the conductive bitlines.

9. The circuit of claim 6, wherein the second conductive electrodes comprise dots of conductive material in lines parallel to the conductive bitlines.

10. The circuit of claim 6, further comprising:
a plurality of vias, wherein a given via of the plurality of vias is in electrical contact with one of the conductive bitlines or wordlines, and wherein an axis along a length of the via is disposed orthogonal to the conductive bitlines and wordlines.

11. The circuit of claim 1, wherein:
the layer of storage material comprises a layer of chalcogenide glass.

12. The circuit of claim 1, further comprising:
a thin dielectric layer between the layer of storage material and the second electrodes.

13. The circuit of claim 1, wherein the storage material of a given memory cell of the array comprises a self-selecting material to select the given memory cell and store data.

14. A system comprising:
a processor; and
a memory communicatively coupled to the processor, the memory including an array of memory cells, wherein the array of memory cells includes:
first conductive electrodes;
a layer of storage material including a nonpatterned region disposed over the first conductive electrodes; and
second conductive electrodes disposed over the nonpatterned region of the storage material;
wherein a given memory cell of the array is located where one of the second conductive electrodes overlaps one of the first conductive electrodes across the nonpatterned region of storage material.

15. The system of claim 14, wherein:
The array of memory cells further includes conductive wordlines in electrical contact with the first electrodes;
wherein spacing between adjacent conductive wordlines is greater than a thickness of the layer of storage material.

16. The system of claim 14, further comprising:
any of a display communicatively coupled to the processor, a network interface communicatively coupled to the processor, or a battery coupled to provide power to the system.

17. A method of forming a circuit including an array of memory cells, the method comprising:
forming first conductive electrodes;
forming a layer of storage material including a nonpatterned region disposed over the first conductive electrodes; and
forming second conductive electrodes over the nonpatterned region of the storage material;
wherein a given memory cell of the array is located where one of the second conductive electrodes overlaps one of the first conductive electrodes across the nonpatterned region of storage material.

18. The method of claim 17, further comprising:
forming conductive wordlines, wherein the first conductive electrodes are formed over the conductive wordlines; and
forming conductive bitlines over the second electrodes;
wherein a distance between adjacent conductive bitlines and between adjacent conductive wordlines is greater than a thickness of the layer of storage material.

19. The method of claim 17, wherein forming the second conductive electrodes comprises:
depositing a second conductive electrode layer; and
patterning the second conductive electrode layer into conductive lines.

20. The method of claim 19, further comprising:
prior to depositing the second conductive electrode layer, forming a thin dielectric layer over the layer of storage material;
wherein patterning the second conductive electrode layer includes etching the second conductive electrode layer and stopping etching before reaching the storage material.
